(19) United States
(12) Patent Application Publication
(10) Pub. No.: US 2019/0354219 A1
(43) Pub. Date: Nov. 21, 2019

(54) DISPLAY DEVICE

(71) Applicant: InnoLux Corporation, Miao-Li County (TW)

(72) Inventors: Kuei-Sheng CHANG, Miao-Li County (TW); Po-Yang CHEN, Miao-Li County (TW); Hsing-Yuan HSU, Miao-Li County (TW); I-An YAO, Miao-Li County (TW)

(21) Appl. No.: 16/390,339

(22) Filed: Apr. 22, 2019

(30) Foreign Application Priority Data
May 15, 2018 (CN) 201810464960.1

(51) Int. Cl. G06F 3/041; H01L 23/498

(52) U.S. Cl. CPC G06F 3/0412; H01L 23/4985; H01L 23/49866; H01L 23/49816

(57) ABSTRACT

A display device includes a first substrate, a second substrate, an icon sensor, a conductive material, and a first conductive pad. The second substrate is provided opposite the first substrate and has a display area and a non-display area. The icon sensor is provided on the first substrate and is disposed at least partially corresponding to the non-display area. The conductive material is provided between the first substrate and the second substrate. The first conductive pad is provided on the second substrate. The icon sensor is electrically connected to the first conductive pad on the second substrate through the conductive material.

### BACKGROUND OF THE INVENTION

### 1. Technical Field

The present disclosure relates to a display device and more particularly to a display device with virtual buttons.

### 2. Description of Related Art

More and more touch-controlled display devices use virtual buttons in place of physical ones to reduce the number of physical components and thereby achieve a thinner and lighter design. However, as virtual buttons must be provided outside the display area of a touch-controlled display device, it is required to connect the virtual buttons to an additional flexible printed circuit board (FPCB) or conductive film so that signals sensed by the virtual buttons can be transmitted to the controller (e.g., an integrated-circuit (IC) element) of the touch-controlled display device. The additional flexible printed circuit board or conductive film not only results in complicated signal transmission paths and thus increases the risk of signal loss during transmission, but generally also needs to be curved or bent to facilitate assembly of the display device such that signal reliability is reduced, meaning the virtual buttons may be inaccurate in sensing a to-be-detected object.

In light of the above, a display device capable of solving the foregoing problems needs to be developed.

### BRIEF SUMMARY OF THE INVENTION

The present disclosure provides a display device whose signal transmission paths are simplified through improvement of component arrangement.

A display device disclosed herein includes a first substrate, a second substrate, an icon sensor, a conductive material, and a first conductive pad. The second substrate is provided opposite the first substrate and has a display area and a non-display area. The icon sensor is provided on the first substrate, and the position of the icon sensor on the first substrate is disposed at least partially corresponding to the non-display area. The conductive material is provided between the first substrate and the second substrate. The first conductive pad is provided on the second substrate. The icon sensor is electrically connected to the first conductive pad on the second substrate through the conductive material.

Another display device disclosed herein includes a first substrate, a second substrate, and an icon sensor. The second substrate is provided opposite the first substrate. The icon sensor is provided on the first substrate and is disposed corresponding to an area outside the second substrate; in other words, the icon sensor does not overlap the second substrate in a direction perpendicular to a first side or a second side of the first substrate. The second substrate is provided with a first conductive pad while the first substrate is provided with a conductive element. The icon sensor is electrically connected to the conductive element, and the conductive element is electrically connected to the first conductive pad through a conductive material.

### BRIEF DESCRIPTION OF THE SEVERAL VIEWS OF THE DRAWINGS

FIG. 1 is a schematic diagram of the display device according to an embodiment of the present disclosure.

FIG. 2 is a partial sectional view taken along line A-A′ across the display device in FIG. 1.

FIG. 3 is a partial sectional view taken along line A-A′ across the display device in FIG. 1.

FIG. 4 is a schematic structural diagram of an embodiment of the present disclosure that adopts a narrow-frame design.

FIG. 5 is a schematic diagram of the display device according to another embodiment of the present disclosure.

FIG. 6 is a partial sectional view taken along line B-B′ across the display device in FIG. 5.

FIG. 7 is a partial sectional view taken along line B-B′ across the display device in FIG. 5.

FIG. 8 is a schematic structural diagram of another embodiment of the present disclosure that adopts a narrow-frame design.

### DETAILED DESCRIPTION OF THE INVENTION

Specific embodiments are described below to demonstrate how to implement the present disclosure. Based on the contents disclosed herein, a person skilled in the art can easily understand other advantages and effects of the present disclosure. The present disclosure can also be implemented or applied in ways different from those demonstrated by the embodiments, and all the details in this specification can be modified or changed to meet different points of view or applications without departing from the spirit of the present creation.

The ordinal numbers used in the specification and the appended claims such as “first” and “second” serve only to modify the claimed elements immediately after them and do not imply that such a claimed element has a counterpart with a previous or subsequent ordinal number, that there is a certain order between such claimed elements, or that such claimed elements are sequentially used in a manufacturing process. The ordinal numbers are used only to provide a clear distinction between claimed elements having the same name.

In addition, when used with reference to time, the term “when . . . ” may denote “during the time that . . . ”, “before . . . ”, or “after . . . ” and does not necessarily mean concurrence. Also, unless otherwise specified, the phrase “provided on . . . ” as used herein to refer to the position of one element in relation to another does not necessarily imply contact between the two elements. Moreover, when a plurality of effects stated herein are joined by the conjunction “or”, those effects may exist independently of one another, but this does not exclude the possibility that some or all of the effects may coexist. Besides, unless otherwise specified, the terms “connected”, “electrically connected”, and “coupled” may denote direct or indirect connection.

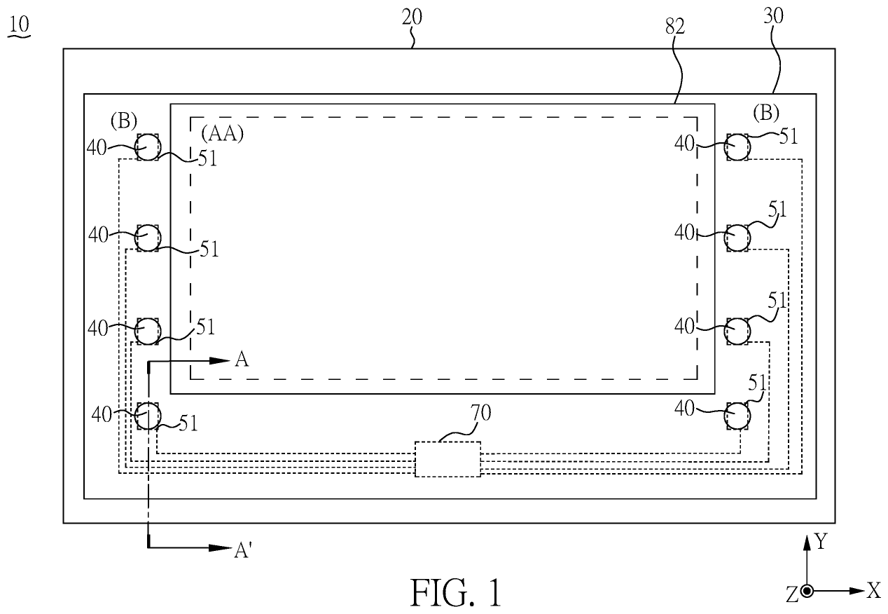

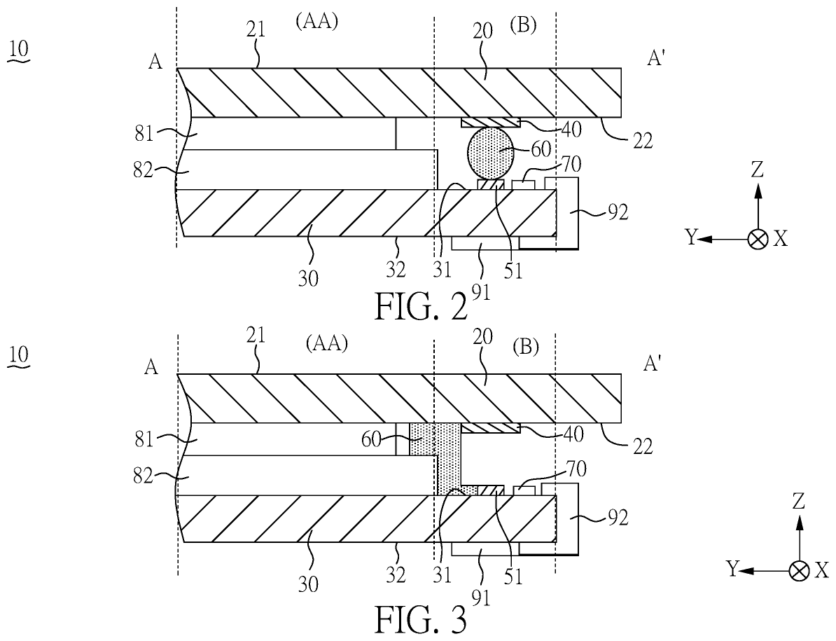

FIG. 1 is a schematic see-through view of the display device 10 according to an embodiment of the present disclosure. As shown in FIG. 1, the display device 10 in this embodiment includes a first substrate 20, a second substrate 30, an icon sensor 40, a conductive material 60 (see FIG. 2), and a first conductive pad 51. The second substrate 30 may be provided opposite the first substrate 20. In the embodiment shown in FIG. 1, the display device 10 is disposed on a first plane (e.g., the XY plane) defined by a first direction (e.g., the X direction) and a second direction (e.g., the Y direction) and has a display side parallel to the first plane and facing to a third direction (e.g., the Z direction, or the display direction). The second substrate 30 may have a display area AA and a non-display area B in the first direction (e.g., the X direction) or the second direction (e.g., the Y direction); in other words, the second substrate 30 may have a display area AA and a non-display area B that are parallel to the display side of the display device 10. The icon sensor 40 may be provided on the first substrate 20, such as on the side of the first substrate 20 that faces, or faces away from, the third direction (e.g., the Z direction). At least a portion of the icon sensor 40 may be disposed corresponding to the non-display area B; that is to say, when viewed in the third direction (e.g., the Z direction), at least a portion of the icon sensor 40 may overlap the non-display area B. For example, the position of the entire icon sensor 40 on the first substrate 20 is disposed corresponding to the non-display area B. Or, the position of a portion of the icon sensor 40 on the first substrate 20 is disposed corresponding to the non-display area B while the position of another portion of the icon sensor 40 on the first substrate 20 is disposed corresponding to the display area AA or an area outside the second substrate 30. The second substrate 30 may be provided with the first conductive pad 51. For example, the side of the second substrate 30 that faces, or faces away from, the third direction (e.g., the Z direction) is provided with the first conductive pad 51. The conductive material 60 is provided between the first substrate 20 and the second substrate 30 such that the icon sensor 40 is electrically connected to the second substrate 30 through the conductive material 60 (see FIG. 2). The first conductive pad 51 may be electrically connected to an integrated-circuit element 70 via, for example, a trace so that sensing signals can be transmitted from the icon sensor 40 to the integrated-circuit element 70. In one embodiment, each of the icon sensor 40 and the shape of the first conductive pad 51 can be any shape, such as a rectangular shape, a circular shape, a polygonal shape, a diamond shape, a triangular shape, a square, an oval shape, or a circularly curved shape, and is sized as appropriate.

In one embodiment, the display device 10 includes more elements than mentioned above, such as but not limited to a printed circuit board (PCB) or a flexible printed circuit board (FPCB).

FIG. 2 is a partial sectional view taken along line A-A′ across the display device 10 in FIG. 1, showing how the icon sensor 40, the conductive material 60, and the first conductive pad 51 are arranged in the second direction (e.g., the Y direction) and the third direction (e.g., the Z direction). To facilitate description, FIG. 2 shows a single icon sensor 40, a single conductive material 60, and a single first conductive pad 51, but in practice the display device 10 may have a plurality of icon sensors 40, a plurality of conductive materials 60, and a plurality of first conductive pads 51 instead. Please also note that certain elements in FIG. 2 have been reduced or increased in size for a clearer view and hence look slightly different from their counterparts in FIG. 1. In FIG. 2, the display area AA and the non-display area B of the display device 10 extend in the second direction (e.g., the Y direction), and the display side of the display device 10 faces the third direction (e.g., the Z direction). Here, the side of the first substrate 20 that faces away from the second substrate 30 is defined as the first side 21 of the first substrate 20, and the side of the first substrate 20 that faces the second substrate 30 is defined as the second side 22 of the first substrate 20. Besides, the side of the second substrate 30 that faces the first substrate 20 is defined as the first side 31 of the second substrate 30, and the side of the second substrate 30 that faces away from the first substrate 20 is defined as the second side 32 of the second substrate 30. The first conductive pad 51 may be provided on the first side 31 of the second substrate 30. The integrated-circuit element 70 may also be provided on the first side 31 of the second substrate 30 and electrically connected to the first conductive pad 51 but is not necessarily so. The icon sensor 40 may be provided on the second side 22 of the first substrate 20. The position of the icon sensor 40 on the second side 22 of the first substrate 20 is disposed at least partially corresponding to the non-display area B of the second substrate 30; in other words, when the position of the icon sensor 40 is projected toward the second substrate 30 in a direction parallel to the third direction (e.g., the Z direction), at least a portion of the projected position is provided in the non-display area B. The conductive material 60 may be provided between the icon sensor 40 and the first conductive pad 51. In one embodiment, the conductive material 60 is directly connected to the icon sensor 40 at one end and to the first conductive pad 51 at the opposite end but is not necessarily so. In another embodiment, one end of the conductive material 60 is connected to the icon sensor 40 through a conductive element (e.g., a trace, a screen-printed metal line, a conductive pad, or a similar element), and the opposite end of the conductive material 60 is connected to the first conductive pad 51 also through a conductive element (e.g., a trace, a screen-printed metal line, a conductive pad, or a similar element). Thus, a sensing signal can be transmitted from the icon sensor 40 sequentially through the conductive material 60 and the first conductive pad 51 to the integrated-circuit element 70 in order to be processed.

The features of the foregoing elements are detailed below with reference to FIG. 1 and FIG. 2.

In one embodiment, the first substrate 20 might be the cover of the display device 10, such as but not limited to a piece of cover glass (CG). The first substrate 20 may be provided as the outermost layer of the display device 10 in the third direction (e.g., the Z direction) so that a user can directly touch the first side 21 of the first substrate 20, and the icon sensor 40 in that case may be provided on the second side 22 of the first substrate 20 to sense the user's touch.

In one embodiment, the second substrate 30 is the display array substrate of the display device 10, with the display area AA having a plurality of display arrays (e.g., pixel unit arrays), and the non-display area B being a border area of the display array substrate. In one embodiment, the pixel units are liquid crystal display (LCD) elements or light-emitting diodes (LEDs), the latter of which include organic LEDs (OLEDs), micro LEDs, quantum-dot LEDs (Q-LEDs), flexible active-matrix OLEDs (AMOLEDs), and so on; the present disclosure has no limitation on the type of pixel units. In one embodiment, and by way of example only, the first substrate 20 has a larger area corresponding to the first plane (e.g., the XY plane) than that of the second substrate 30 corresponding to the first plane (e.g., the XY plane); therefore, once the display device 10 is assembled, the area of the first substrate 20 encompasses that of the second substrate 30, but the present disclosure is not limited thereto. In another embodiment, the area of the first substrate 20 (corresponding to the first plane) is equal to or smaller than that of the second substrate 30. To facilitate description, the first substrate 20 in each of the following embodiments has a larger area corresponding to the first plane than the second substrate 30 by way of example.

In one embodiment, the icon sensor 40 is a metal layer, an electrode, a patterned metal layer, or a conductive substance. In one embodiment, the shape of the icon sensor 40 can be any shape. In one embodiment, and by way of example only, the icon sensor 40 has a transparent, translucent, or opaque structure. In one embodiment, the icon sensor 40 being provided on the first substrate 20 and corresponding to the non-display area B of the second substrate 30 is defined as the icon sensor 40 having at least one portion located in an area of the first substrate 20 that is disposed corresponding to the non-display area B. For example, it is feasible for the position of the entire icon sensor 40 on the first substrate 20 to be corresponding to the non-display area B, or for the position of only a portion of the icon sensor 40 on the first substrate 10 to be corresponding to the non-display area B while the position of another portion of the icon sensor 40 on the first substrate 20 is disposed corresponding to neither the display area AA nor the non-display area B; the present disclosure has no limitation in this regard. Please note that the icon sensor 40 may be positioned according to the position of the first conductive pad 51 on the second substrate 30. More specifically, the icon sensor 40 and the first conductive pad 51 must be so positioned that the conductive material 60 can connect to the icon sensor 40 and the first conductive pad 51 at two ends respectively. In one embodiment, the icon sensor 40 can detect a user's touch by various methods, such as but not limited to resistive sensing, capacitive sensing, and optical sensing. The sensing method of the icon sensor is not a critical feature of the present disclosure and therefore will not be dealt with in more detail.

In one embodiment, the first conductive pad 51 is provided in the non-display area B. In one embodiment, there is no limitation in size on the first conductive pad 51 or the icon sensor 40. The first conductive pad 51 comprises any suitable conductive material; the present disclosure has no limitation in this regard. In addition, the first conductive pad 51 may be provided adjacent to the integrated-circuit element 70 but is not necessarily so.

In one embodiment, the conductive material 60 is a material capable of electrical conduction through two opposite sides, such as but not limited to a solder ball, conductive copper foil, or silver paste. In one embodiment, the conductive material 60 has an electrical resistivity equal to 10⁻¹⁰ Ω*m, or greater than 10⁻¹⁰ Ω*m but lower than 10⁻¹ Ω*m, or equal to 10⁻¹ Ω*m. As shown in FIG. 2, the conductive material 60 in this embodiment might be a solder ball and has a first end point connected to the icon sensor 40 and a second end point connected to the first conductive pad 51. Thus, the icon sensor 40 and the first conductive pad 51 are connected via the solder ball, and a sensing signal transmission path is formed directly by the icon sensor 40, the solder ball, and the first conductive pad 51. This signal transmission path does not require an additional curved/bent circuit board and is therefore simpler than its prior art counterparts and helpful in increasing the reliability of sensing signals.

In one embodiment, the integrated-circuit element 70 is provided on the first side 31 of the second substrate 30, such as in the non-display area B. In other embodiments, the integrated-circuit element 70 may be provided on the second side 32 of the second substrate 30 or in an area outside the second substrate 30 and be connected to the first conductive pad 51 through, for example, a trace. In one embodiment, the integrated-circuit element 70 is a TDDI (touch and display driver integration) integrated-circuit element, meaning the integrated-circuit elements in the display device 10 that are intended for touch control and display respectively in the first place are actually integrated together. In one embodiment, and by way of example only, the integrated-circuit element 70 is provided on the display array substrate (i.e., in an in-cell touch panel configuration). In one embodiment, and by way of example only, the integrated-circuit element 70 is provided outside the display array substrate, such as on a polarization layer substrate (i.e., in an on-cell touch panel configuration), or is provided outside the panel area (i.e., in an out-of-cell touch panel configuration). In another embodiment, and by way of example only, the integrated-circuit element 70 is configured to process signals from the icon sensor 40 but not signals related to touch control or display over the display array area.

In one embodiment, the display device 10 further includes a polarization layer 81 and a third substrate 82, wherein the third substrate 82 may comprise but is not limited to a color filter layer. In one embodiment, the polarization layer 81 and the third substrate 82 are provided between the first substrate 20 and the second substrate 30 in the third direction (e.g., the Z direction). In one embodiment, and by way of example, the third substrate 82 is arranged in the third direction, e.g. it is provided on the first side 31 of the second substrate 30; besides, the polarization layer 81 is arranged in the third direction, e.g. it is provided on the side of the third substrate 82 that faces away from the second substrate 30. Apart from the polarization layer 81 and the third substrate 82, more stacked structures may be provided between the first substrate 20 and the second substrate 30. For example, additional structures may be stacked between the third substrate 82 and the second substrate 30, between the third substrate 82 and the polarization layer 81, or between the polarization layer 81 and the first substrate 20.

As the present disclosure does not require an additional flexible printed circuit board or conductive film, the icon sensor 40 in one embodiment can be made together with traces on the first substrate 20 using the same photomask, and the first conductive pad 51 in one embodiment can be made together with traces on the second substrate 30 using the same photomask. Thus, the present disclosure allows simplification of its manufacturing process.

In this embodiment, the display device 10 may further include a printed circuit board assembly (PCBA) 91. During assembly of the display device 10, the printed circuit board assembly 91 is curved or bent along the second side 32 of the second substrate 30 and is connected to the integrated-circuit element 70 through, for example, a panel connect unit 92. However, the present disclosure is not limited thereto. In one embodiment, and by way of example only, the panel link is a flexible printed circuit board, trace, or other element having a electrical connection function and is curved or bent along the first side 31 of the second substrate 30 and the second side 32 of the second substrate 30. In one embodiment, the printed circuit board assembly 91 is integrated with the panel connect unit 92. Conventionally, it would have been required to connect the icon sensor 40 to an additional flexible printed circuit board or conductive film to enable transmission of sensing signals, and due to mechanism restrictions, the additional flexible printed circuit board or conductive film would have to be provided in a spare area outside the display array substrate (e.g., the second substrate 30) and therefore be curved or bent in advance in order to connect with the printed circuit board assembly 91 on the second side 32 of the second substrate 30, resulting in a long and complicated sensing signal transmission path, which is formed by the icon sensor 40, the additional flexible printed circuit board or conductive film, the printed circuit board assembly 91, the panel connect unit 92, and the integrated-circuit element 70 and may compromise signal reliability. By contrast, the sensing signal transmission path disclosed herein is simpler and hence free of the foregoing problems.

Please refer to FIG. 3 in conjunction with FIG. 1 and FIG. 2. FIG. 3 is a partial sectional view taken along line A-A′ across the display device 10 in FIG. 1 according to another embodiment of the present disclosure, showing another arrangement of the icon sensor 40, the conductive material 60, and the first conductive pad 51 in the second direction (e.g., the Y direction) and the third direction (e.g., the Z direction). The number and sizes of the elements in this embodiment are only illustrative, and certain elements in FIG. 3 have been reduced or increased in size for a clearer view and hence look slightly different from their counterparts in FIG. 1. The display device 10 in this embodiment also includes a first substrate 20, a second substrate 30, an icon sensor 40, a first conductive pad 51, a conductive material 60, and an integrated-circuit element 70. In one embodiment, the display device 10 further includes, for example but not limited to, a polarization layer 81 and a third substrate 82. In one embodiment, the third substrate 82 may comprise but is not limited to a color filter layer. In one embodiment, the display device 10 further includes, for example but not limited to, a printed circuit board assembly 91 and a panel connect unit 92. The foregoing elements may have the same detailed features and arrangement as in the embodiment described with reference to FIG. 2 and therefore will not be described repeatedly; the following paragraphs deal with only the differences between the embodiments in FIG. 2 and FIG. 3.

As shown in FIG. 3, the conductive material 60 in this embodiment is silver paste. In one embodiment, the silver paste is applied to the first side 31 of the second substrate 30 and is in contact with and thus electrically connected to the first conductive pad 51. In one embodiment, the silver paste is not in contact with the polarization layer 81. In another embodiment, and by way of example only, the silver paste is in contact with the polarization layer 81 to guide the static electricity generated by the polarization layer 81 to the integrated-circuit element 70 or a specific element and thereby remove the static electricity. In one embodiment, and by way of example only, the silver paste is also in contact with the third substrate 82. Thus, the sensing signal transmission path of the icon sensor 40 in this embodiment is formed by the icon sensor 40, the silver paste, the first conductive pad 51, and the integrated-circuit element 70 and is still simple and therefore helpful in increasing signal reliability. It is worth mentioning that the conductive material in the present disclosure is not limited to silver paste or solder balls and may also include conductive copper foil for example, provided that the conductive material 60 is capable of electrical conduction through two opposite sides.

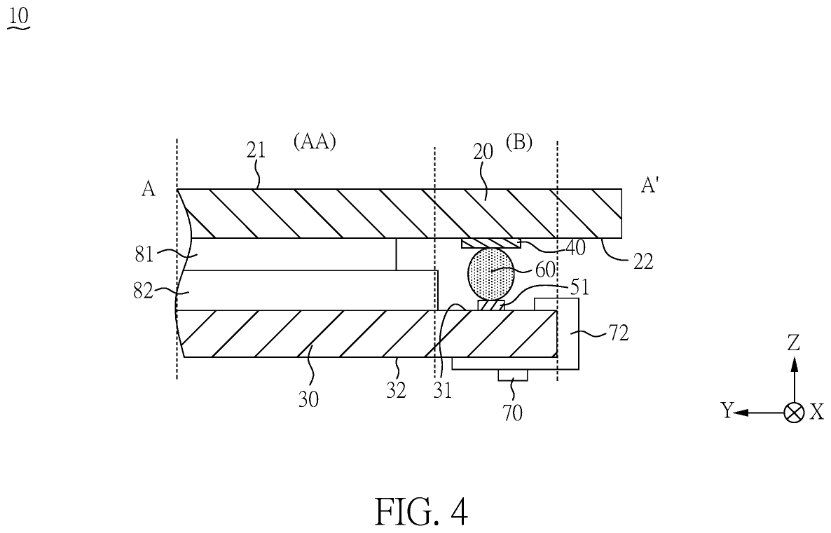

Please refer to FIG. 4 in conjunction with FIG. 1 to FIG. 3. FIG. 4 is a schematic structural diagram of an embodiment of the present disclosure that adopts a narrow-frame design, i.e., an embodiment in which a narrow-frame design is applied to the present disclosure. The sectional view in FIG. 4 is taken along the same section line as in FIG. 2 and FIG. 3. The number and sizes of the elements in this embodiment are only illustrative. As shown in FIG. 4, the display device 10 in this embodiment also includes a first substrate 20, a second substrate 30, an icon sensor 40, a first conductive pad 51, a conductive material 60, and an integrated-circuit element 70. The first substrate 20, the second substrate 30, the icon sensor 40, the first conductive pad 51, and the conductive material 60 can be understood through the foregoing embodiments and therefore will not be described repeatedly. This embodiment is different from the previous embodiments in that the integrated-circuit element 70 is located on the second side 32 of the second substrate 30, is provided on a connecting substrate 72, and is connected to the first conductive pad 51 through the connecting substrate 72 to reduce the frame width of the display device 10. In one embodiment, the connecting substrate 72 is integrated with the integrated-circuit element 70 by, for example, the chip-on-film (COF) technique in order to achieve a narrow-frame design. The chip-on-film technique is not a critical feature of the present disclosure and hence will not be explained in more detail. The sensing signal transmission path of the icon sensor 40 in this embodiment is formed by the icon sensor 40, the conductive material 60, the first conductive pad 51, the connecting substrate 72, and the integrated-circuit element 70. The path of this embodiment is simpler than its prior art counterparts and therefore also contributes to increasing the reliability of sensing signals. Furthermore, the chip-on-film technique enables this embodiment to satisfy the requirements of a narrow-frame design.

While the conductive material 60 in FIG. 4 is depicted as a solder ball, the conductive material 60 in this embodiment may alternatively be silver paste (see FIG. 3) or other conductive materials that provide electrical conduction through two opposite sides. A polarization layer 81 may also be provided between the first substrate 20 and the second substrate 30 in this embodiment. When the conductive material 60 is silver paste, the silver paste may be connected to the polarization layer 81, if so desired, with a view to removing the static electricity generated by the polarization layer 81. However, the present disclosure is not limited thereto.

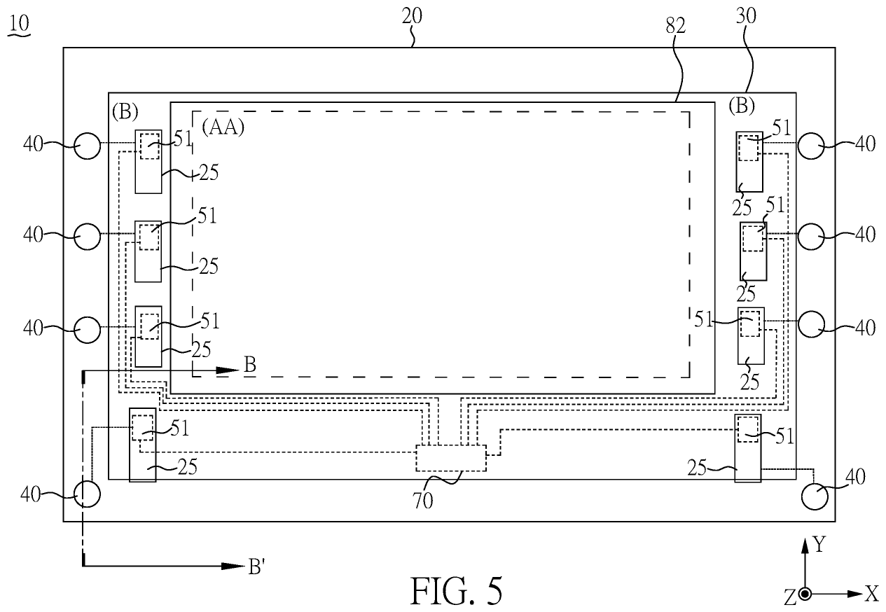

The icon sensor 40 in the present disclosure is not necessarily provided at a position corresponding to the non-display area B. Referring to FIG. 5 for a schematic see-through view of the display device 10 according to another embodiment of the present disclosure, the display device 10 in this embodiment includes a first substrate 20, a second substrate 30, and an icon sensor 40. The second substrate 30 may be provided opposite the first substrate 20. When the display device 10 is disposed on a first plane (e.g., the XY plane), a display area AA and a non-display area B of the second substrate 30 extend in a first direction (e.g., the X direction) or a second direction (e.g., the Y direction), i.e., parallel to the display side of the display device 10. The icon sensor 40 may be provided on the first substrate 20 and disposed corresponding to an area outside the second substrate 30. For example, the position of the icon sensor 40 on the first substrate 20 is corresponding to an area outside the second substrate 30 (i.e., when viewed in a direction perpendicular to a first side 21 or a second side 22 of the first substrate 20, the icon sensor 40 does not overlap the second substrate 30). A conductive element 25 is provided on the first substrate 20. The icon sensor 40 may be connected to the conductive element 25, and the conductive element 25 may in turn be connected to a first conductive pad 51 on the second substrate 30 through a conductive material 60 (as shown in FIG. 6). In one embodiment, the first conductive pad 51 is electrically connected to an integrated-circuit element 70 in order for a sensing signal to be transmitted from the icon sensor 40 to the integrated-circuit element 70.

The first substrate 20, the second substrate 30, the icon sensor 40, the first conductive pad 51, the conductive material 60, and the integrated-circuit element 70 of the display device 10 in this embodiment may have the same detailed features as in the foregoing embodiments. The following paragraphs describe only the distinctive features of the display device 10 in this embodiment.

Please refer to FIG. 6 in conjunction with FIG. 5. FIG. 6 is a partial sectional view taken along line B-B′ across the display device 10 in FIG. 5, showing how the icon sensor 40, the conductive element 25, the conductive material 60, and the first conductive pad 51 are arranged in the second direction (e.g., the Y direction) and the third direction (e.g., the Z direction). The number and sizes of the elements in this embodiment are only illustrative, and certain elements in FIG. 6 have been reduced or increased in size for a clearer view and hence look slightly different from their counterparts in FIG. 5. As shown in FIG. 6, the second substrate 30 has a first side 31 facing the third direction (e.g., the Z direction, or the display direction). The first conductive pad 51 may be provided on the first side 31 of the second substrate 30. The integrated-circuit element 70 may be provided on the first side 31 of the second substrate 30 and electrically connected to the first conductive pad 51. The icon sensor 40 may be provided on the second side 22 of the first substrate 20. The position of the icon sensor 40 on the second side 22 of the first substrate 20 may be corresponding to an area outside the second substrate 30; in other words, when the position of the icon sensor 40 is projected toward the second substrate 30 in a direction parallel to the third direction (e.g., the Z direction), the projected position lies outside the second substrate 30. The conductive element 25 may be provided on the second side 22 of the first substrate 20 and connected to the icon sensor 40. In one embodiment, the position of the conductive element 25 on the first substrate 20 is disposed corresponding to the non-display area B. In one embodiment, and by way of example only, the position of the conductive element 25 on the first substrate 20 is disposed corresponding to the first conductive pad 51. The conductive material 60 may be provided between the conductive element 25 and the first conductive pad 51. The conductive material 60 may have one end electrically connected to the icon sensor 40 via the conductive element 25, and the opposite end connected to the first conductive pad 51. Thus, a signal can be transmitted from the icon sensor 40 through the conductive element 25 and the conductive material 60 to the first conductive pad 51, and then from the first conductive pad 51 to the integrated-circuit element 70 in order to be processed. In this embodiment, the conductive material 60 may be a solder ball, with one end directly connected to the conductive element 25 and the opposite end directly connected to the first conductive pad 51.

In one embodiment, the display device 10 further includes a polarization layer 81 and a third substrate 82. In one embodiment, the third substrate 82 may comprise but is not limited to a color filter layer. In one embodiment, the display device 10 further includes a printed circuit board assembly 91 and a panel connect unit 92. Please note that the foregoing additional structures are only exemplary but not limiting.

In one embodiment, the conductive element 25 is a metal line screen-printed on the first substrate 20 (such as but not limited to a glass substrate) and connected to the icon sensor 40. In another embodiment, the conductive element 25 is a conductive pad (i.e. the conductive element 25 can be regarded as a second conductive pad of the display device 10) provided on the first substrate 20 (such as but not limited to a glass substrate) and connected to the icon sensor 40. The conductive element 25, however, is not limited to the above two configurations.

This embodiment does not require an additional flexible printed circuit board or conductive film but has a simple signal transmission path that helps increase the reliability of sensing signals.

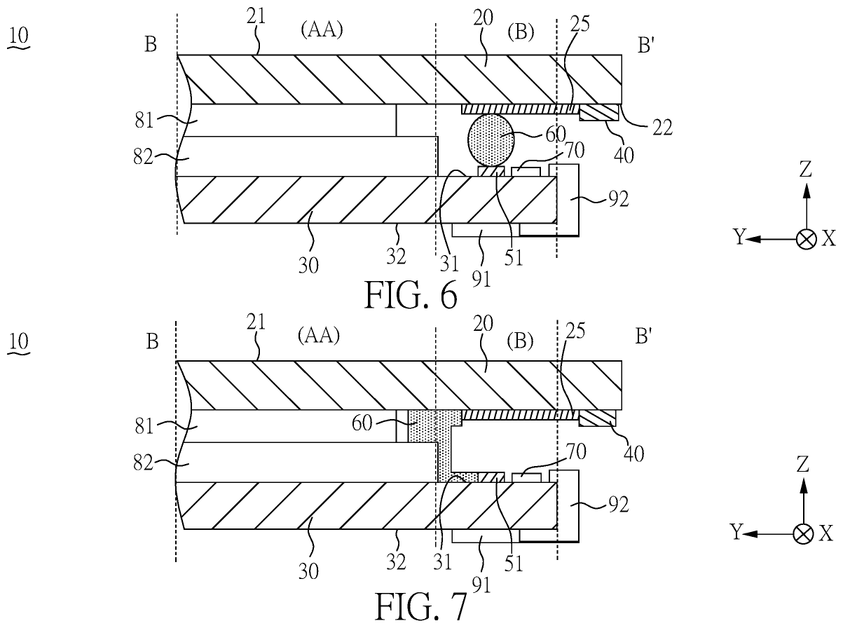

Please refer to FIG. 7 in conjunction with FIG. 5 and FIG. 6. FIG. 7 is a partial sectional view taken along line B-B′ across the display device 10 in FIG. 5 according to another embodiment of the present disclosure, showing another arrangement of the icon sensor 40, the conductive material 60, and the first conductive pad 51 in the second direction (e.g., the Y direction) and the third direction (e.g., the Z direction). The number and sizes of the elements in this embodiment are only illustrative, and certain elements in FIG. 7 have been reduced or increased in size for a clearer view and hence look slightly different from their counterparts in FIG. 5. The display device 10 in this embodiment also includes a first substrate 20, a second substrate 30, a icon sensor 40, a first conductive pad 51, a conductive material 60, and an integrated-circuit element 70. In one embodiment, the display device 10 further includes a polarization layer 81 and a third substrate 82. In one embodiment, the third substrate 82 may comprise but is not limited to color filter layer. In one embodiment, and by way of example only, the display device 10 further includes a printed circuit board assembly 91 and a panel connect unit 92. The foregoing elements may have the same detailed features and arrangement as in the embodiment described with reference to FIG. 6 and therefore will not be described repeatedly.

The conductive material 60 in this embodiment is silver paste. In one embodiment, the silver paste is applied to the first side 31 of the second substrate 30 and connected to the first conductive pad 51. In one embodiment, the silver paste is not in contact with the polarization layer 81, but in another embodiment, the silver paste is connected to the polarization layer 81 to guide the static electricity generated by the polarization layer 81 to the integrated-circuit element 70 and thereby remove the static electricity. This embodiment does not require an additional flexible printed circuit board or conductive film either, but has a simple signal transmission path that helps increase the reliability of sensing signals.

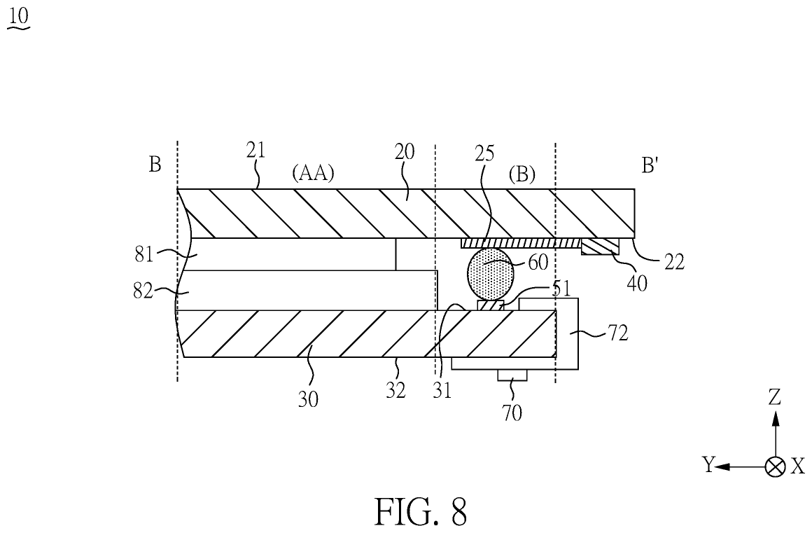

Please refer to FIG. 8 in conjunction with FIG. 5 to FIG. 7. FIG. 8 is a schematic structural diagram of another embodiment of the present disclosure that adopts a narrow-frame design. The number and sizes of the elements in this embodiment are only illustrative. As shown in FIG. 8, the display device 10 in this embodiment also includes a first substrate 20, a second substrate 30, an icon sensor 40, a conductive element 25, a first conductive pad 51, a conductive material 60, and an integrated-circuit element 70. The first substrate 20, the second substrate 30, the icon sensor 40, the first conductive pad 51, the conductive material 60, and the conductive element 25 can be understood through the foregoing embodiments and therefore will not be described repeatedly.

To achieve a narrow-frame design, the integrated-circuit element 70 in this embodiment is provided on a connecting substrate 72 by the chip-on-film technique, and the connecting substrate 72 is electrically connected to the first conductive pad 51. The connecting substrate 72 and the integrated-circuit element 70 can be understood through the embodiment described with reference to FIG. 4 and hence will not be detailed repeatedly. The sensing signal transmission path of the icon sensor 40 in this embodiment is formed by the icon sensor 40, the conductive element 25, the conductive material 60, the first conductive pad 51, the connecting substrate 72 and the integrated-circuit element 70. Simpler than its conventional technical, this path not only helps increase the reliability of sensing signals, but also satisfies the requirements of a narrow-frame design.

The display device 10 disclosed herein can be used in combination with a touch panel to form a touch-controlled display device. Furthermore, a display device or touch-controlled display device made according to the embodiments disclosed herein can be used in any electronic devices in the art that require a display screen, such as displays, mobile phones, laptop computers, video cameras, still cameras, music players, mobile navigation devices, television sets, automotive dashboards, center consoles, electronic rear-view mirrors, overhead displays, and other electronic devices that are designed to display images.

The present disclosure provides an improved display device 10, whose icon sensor has a much simpler sensing signal transmission path than its conventional counterparts so that signal reliability is enhanced. In addition, by changing the arrangement of its elements, the disclosed display device 10 can adapt to a narrow-frame design to be in line with the current market trend.

The embodiments provided herein serve illustrative purposes only. The scope of patent protection sought by the applicant is defined by the appended claims rather than limited to the disclosed embodiments.

What is claimed is:

1. A display device, comprising:
a first substrate;
a second substrate provided opposite the first substrate, wherein the second substrate has a display area and a non-display area;
an icon sensor provided on the first substrate and disposed at least partially corresponding to the non-display area;
a conductive material provided between the first substrate and the second substrate; and
a first conductive pad provided on the second substrate;
wherein the icon sensor is electrically connected to the first conductive pad on the second substrate through the conductive material.

2. The display device of claim 1, wherein the non-display area is provided with an integrated-circuit element, and the first conductive pad is electrically connected to the integrated-circuit element.

3. The display device of claim 1, wherein the second substrate has a side facing away from the first substrate and provided with an integrated-circuitelement, and the integrated-circuit element is electrically connected to the first conductive pad by a chip-on-film technique.

4. The display device of claim 1, wherein the conductive material has an electrical resistivity ranging from 10⁻¹⁰ Ω*m to 10⁻¹ Ω*m inclusive.

5. The display device of claim 1, wherein the conductive material has a first end point and a second end point, the first end point is connected to the icon sensor, and the second end point is connected to the first conductive pad.

6. The display device of claim 1, wherein the conductive material is a silver paste, and the silver paste is in contact with the icon sensor and the first conductive pad.

7. The display device of claim 1, further comprising a third substrate provided between the first substrate and the second substrate, wherein the third substrate comprises a color filter layer.

8. The display device of claim 1, wherein the first conductive pad is provided in the non-display area.

9. The display device of claim 1, further comprising a polarization layer provided between the first substrate and the second substrate.

10. The display device of claim 9, wherein the conductive material is a silver paste, and the silver paste is in contact with the icon sensor, the polarization layer and the first conductive pad.

11. A display device, comprising:
a first substrate;
a second substrate provided opposite the first substrate; and
a icon sensor provided on the first substrate and disposed corresponding to an area outside the second substrate;
wherein the second substrate is provided with a first conductive pad, the first substrate is provided with a conductive element, the icon sensor is electrically connected to the conductive element, and the conductive element is electrically connected to the first conductive pad through a conductive material.

12. The display device of claim 11, wherein a non-display area is provided with an integrated-circuit element, and the first conductive pad is electrically connected to the integrated-circuit element.

13. The display device of claim 11, wherein the second substrate has a side facing away from the first substrate and provided with an integrated-circuit element, and the integrated-circuit element is electrically connected to the first conductive pad by a chip-on-film technique.

14. The display device of claim 11, wherein the conductive material has an electrical resistivity ranging from 10⁻¹⁰ Ω*m to 10⁻¹ Ω*m inclusive.

15. The display device of claim 11, wherein the second substrate has a display area having a plurality of display arrays and a non-display area being a border area of the display array substrate

16. The display device of claim 15, wherein the first conductive pad is provided on the non-display area.

17. The display device of claim 11, further comprising a polarization layer provided between the first substrate and the second substrate.

18. The display device of claim 17, wherein the conductive material is a silver paste, and the silver paste is in contact with the icon sensor, the polarization layer and the first conductive pad.

19. The display device of claim 11, further comprising a third substrate provided between the first substrate and the second substrate.

20. The display device of claim 19, wherein the third substrate comprises a color filter layer.
